(19) United States
(12) Patent Application Publication
(10) Pub. No.: US 2012/0244656 A1
(43) Pub. Date: Sep. 27, 2012

(54) METHOD AND APPARATUS FOR PRODUCING SOLAR CELL

(75) Inventors: Jae Hoon KIM, Seoul (KR); Jin Mun RYU, Gyeonggi-do (KR); Seung Yun OH, Gyeonggi-do (KR); In Taek SONG, Gyeonggi-do (KR); Tae Young KIM, Seoul (KR)

(73) Assignee: SAMSUNG ELECTRO-MECHANICS CO., LTD.

(21) Appl. No.: 13/342,511

(22) Filed: Jan. 3, 2012

(30) Foreign Application Priority Data
Mar. 25, 2011 (KR) 10-2011-0026951

(51) Int. Cl. H01L 31/18; B29B 13/08

(52) U.S. Cl. 438/68; 425/142; 257/E31.001

(57) ABSTRACT

Disclosed herein are a method and an apparatus for producing a solar cell. The method includes: (a) preparing a rear contact solar cell substrate having electrode patterns formed on a rear surface thereof; (b) performing scribing on a front surface of the substrate on which the electrode patterns are not formed, by using laser; and (c) cutting the substrate in each cell along the scribing so as to form the solar cell. Further, an apparatus for producing a solar cell is operated by the method for producing a solar cell.

### CROSS REFERENCE(S) TO RELATED APPLICATIONS

This application claims the benefit under 35 U.S.C. Section 119 of Korean Patent Application Serial No. 10-2011-0026951, entitled “Method And Apparatus For Producing Solar Cell” filed on Mar. 25, 2011, which is hereby incorporated by reference in its entirety into this application.

### BACKGROUND OF THE INVENTION

1. Technical Field

The present invention relates to a method and an apparatus for producing a solar cell. The present invention relates to a method and an apparatus for cutting a solar cell in a wafer substrate unit into a cell unit at a required size so as to manufacture a small solar cell (low output) rather than a solar cell for power generation. More particularly, the present invention relates to a method and an apparatus for producing a solar cell by cutting each cell by performing laser scribing.

2. Description of the Related Art

Recently, research and development of a solar cell as a clean energy source has actively progressed due to an increase in oil price, depletion of fossil fuels, environmental problems, or the like. Application fields of the solar cell have also been widely applied from power generation to general electronic devices.

The solar cell is a device that converts light energy into electric energy using a photoelectric effect or a photovoltaic effect. The solar cell is classified into a silicon solar cell, a thin film solar cell, a dye sensitized solar cell, an organic polymer solar cell, or the like, according to the structure material thereof. Today, a silicon solar cell dominates the market. The silicon solar cell is generally configured of a semiconductor in which a p-n junction is made. Further, a solar cell module is formed by connecting the solar cells in parallel or in series according to required electric capacity.

Voltage that can be generated by each cell of the solar cell is affected by the used semiconductor material. Generally, about 0.5 V is generated in the case of using silicon. However, cells connected to each other in series are generally used so as to obtain higher voltage.

In the related art, in order to manufacture a small solar cell with a desired size, a method for cutting a solar cell in a wafer unit by using a diamond blade is used. The blade cutting is a method capable of most conveniently and easily cutting the solar cell in the wafer substrate unit into a cell unit at a desired size. However, the diamond blade cutting performs cutting while breaking a micro structure of the solar cell in the wafer unit that is a sample, such that many defects such as chipping, cracks, or the like, may occur at corners and side portions of the cut cell. These defects cause degradation of the conversion efficiency of the solar cell. In the worse case, the conversion efficiency is degraded more than 5% after the solar cell in the wafer substrate unit is cut into a cell unit, rather than in the state of the wafer.

### SUMMARY OF THE INVENTION

An object of the present invention is to cut a wafer so as to minimize degradation in conversion efficiency even after a solar cell in a wafer substrate unit, in particular, a rear contact solar cell in a wafer unit is cut into a cell unit during manufacturing a small solar cell.

In particular, another object of the present invention is to prevent degradation in conversion efficiency of a solar cell due to an electrode damage caused at the time of laser processing, by cutting a rear contact solar cell in a wafer substrate unit into a cell unit, by performing laser scribing on a top surface of the rear contact solar cell on which electrode patterns are not formed rather than on the rear surface of the rear contact solar cell on which electrodes are formed.

According to an exemplary embodiment of the present invention, there is provided a method for producing a solar cell, including: (a) preparing a rear contact solar cell substrate having electrode patterns formed on a rear surface thereof; (b) performing scribing on a front surface of the substrate on which the electrode patterns are not formed, by using laser; and (c) cutting the substrate in each cell along the scribing so as to form the solar cell.

At the step (b), the scribing may be performed in at least one direction including a direction vertical to the electrode patterns.

At the step (a), the prepared substrate may have positive (+) and negative (−) electrode patterns penetrating through a passivation pattern and alternately formed on the rear surface thereof.

The method for producing a solar cell may further include detecting defects that detect defective portions by a photoluminescence method prior to the step (c) after the step (b).

The method for producing a solar cell may further include marking on the cell determined as defects after the step of detecting defects.

After the step (c), the cut cells may be divided as good products and defective products.

The laser used for the scribing may have a wavelength according to one of infrared, visible, and ultraviolet bands.

According to an exemplary embodiment of the present invention, there is provided an apparatus for producing a solar cell, including: a control unit that controls an operation of each component; a stage unit that transfers a rear contact solar cell substrate having electrode patterns formed on a rear surface thereof according to a control of the control unit; a scribing unit that performs scribing by irradiating laser to a front surface of the substrate transferred through the stage unit on which the electrode patterns are not formed; and a cell cutting unit that accepts the scribed substrate through the stage unit and cuts the substrate in each cell along the scribing so as to form the solar cell.

The scribing unit may perform the scribing in at least one direction including a direction vertical to the electrode patterns. The substrate transferred through the stage unit may include positive (+) and negative (−) electrode patterns and alternately formed on the rear surface thereof, the positive (+) and negative (−) electrode patterns penetrating through a passivation pattern.

The scribing unit may include an air nozzle that removes foreign materials on the surface of the substrate.

The scribing unit may include a reflection mirror that reflects laser irradiated from a laser irradiator and a focusing lens that focuses the reflected laser.

The cell cutting unit may cut the substrate along scribed grooves performed by the scribing unit by applying the tension stress or the shear stress thereto.

The apparatus for producing a solar cell may further include a photoluminescence unit that captures an emission image by irradiating laser to the scribed substrate, wherein defective portions are read and detected from the image captured from the photoluminescence unit.

The photoluminescence unit may include a marker that marks a cell including the detected defective portions.

The laser irradiated from the scribing unit may have a wavelength according to one of infrared, visible, and ultraviolet bands.

### BRIEF DESCRIPTION OF THE DRAWINGS

FIG. 1 is a flow chart schematically showing a method for producing a solar cell according to an exemplary embodiment of the present invention.

FIG. 2 is a flow chart schematically showing a method for producing a solar cell according to another exemplary embodiment of the present invention.

FIG. 3 is a diagram schematically showing a scribing direction according to an exemplary embodiment of the present invention.

FIG. 4 is a diagram showing an image captured by a photoluminescence method after performing scribing on a wafer substrate according to an exemplary embodiment of the present invention.

FIG. 5 is a diagram schematically showing an apparatus for producing a solar cell according to another exemplary embodiment of the present invention.

### DESCRIPTION OF THE PREFERRED EMBODIMENTS

Exemplary embodiments of the present invention for accomplishing the above-mentioned objects will be described with reference to the accompanying drawings. In describing exemplary embodiments of the present invention, the same reference numerals will be used to describe the same components and an additional description that is overlapped or allow the meaning of the present invention to be restrictively interpreted will be omitted.

It will be understood that when an element is referred to as simply being “coupled to” or “connected to” another element rather than being “directly coupled to” or “directly connected to” another element in the present description, it can be directly connected with the other element or may be connected with another element, having other element coupled or connected therebetween, as long as it is not contradictory to the description or is opposite to the concept of the present invention

Although a singular form is used in the present description, it may include a plural form as long as it is opposite to the concept of the present invention and is not contradictory in view of interpretation or is used as clearly different meaning. It should be understood that “include”, “have”, “comprise”, “be configured to include”, and the like, used in the present description do not exclude presence or addition of one or more other characteristic, component, or a combination thereof.

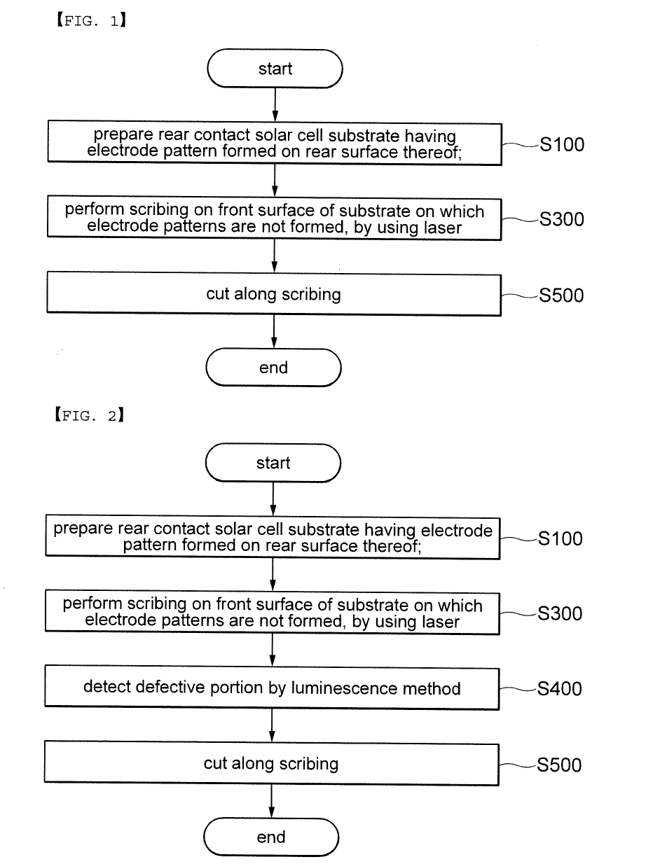

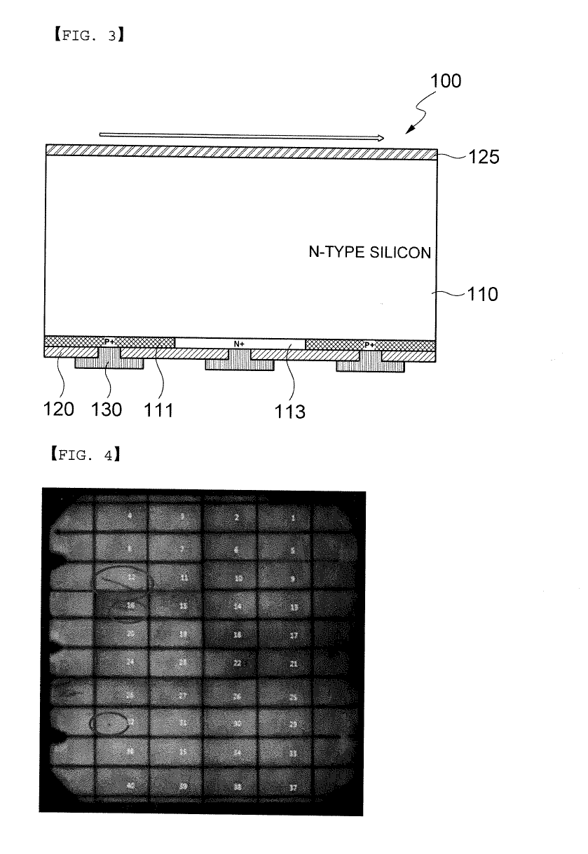

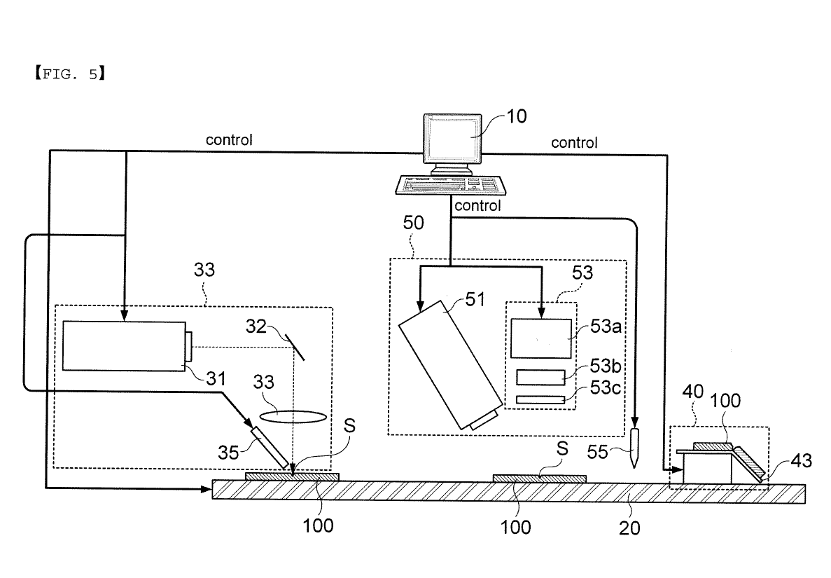

FIG. 1 is a flow chart schematically showing a method for producing a solar cell according to an exemplary embodiment of the present invention, FIG. 2 is a flow chart schematically showing a method for producing a solar cell according to another exemplary embodiment of the present invention, FIG. 3 is a diagram schematically showing a scribing direction according to an exemplary embodiment of the present invention, and FIG. 4 is a diagram showing an image captured by a photoluminescence method after performing scribing on a wafer substrate according to an exemplary embodiment of the present invention. Further, FIG. 5 is a diagram schematically showing an apparatus for producing a solar cell according to another exemplary embodiment of the present invention.

First, a method for producing a solar cell according to an exemplary embodiment of the present invention will be described with reference to FIGS. 1 to 3.

Referring to FIG. 1, a method for producing a solar cell according to an exemplary embodiment of the present invention is configured to include the following steps (a) to (c) (S100 to S300).

At the step (a) (S100), a rear contact solar cell substrate 100 having electrode patterns 130 formed on a rear surface thereof is prepared. In the exemplary embodiment of the present invention, the solar cell substrate 100 means, for example, the fact that a solar cell is formed on a substrate in a wafer unit. In the exemplary embodiment of the present invention, the rear contact solar cell means the fact that positive (+) and negative (−) electrodes 130 both are formed on a rear surface thereof. Generally, anti-reflection coating (not shown) is not performed on the front surface of the solar cell.

Referring to FIG. 3, preferably, according to an exemplary embodiment of the present invention, at the step (a) (S100), the positive (+) and negative (−) electrode patterns penetrating through an oxide layer or a passivation pattern (passivation layer) 120 are alternately disposed on the rear surface of the prepared solar cell substrate 100. In FIG. 3, reference numeral 110 represents an n-type silicon wafer, reference numeral 111 represents a region in which p-type impurity is doped, reference numeral 113 represents a region in which n-type impurity is doped, reference numeral 120 represents a passivation layer or an oxide layer, and reference numeral 125 represents an oxide layer. Reference numeral 100 is, for example, the solar cell substrate 100 that represents the solar cell in a wafer unit. FIG. 3 is a diagram showing a cross section of the solar cell, wherein the electrode pattern 130 is formed in a direction vertical to a ground of FIG. 3.

Next, at the step (b) (S300), the laser scribing is performed on a front surface of the solar cell substrate 100 on which the electrode patterns 130 are not formed. In the exemplary embodiment of the present invention, as a microstructure of the wafer substrate is broken due to the cutting of the wafer substrate by a diamond blade of the related art, many defects occur at the corners of the solar cell, or the like, to degrade the conversion efficiency in the solar cell. In order to solve the above problem, the scribing is performed in a cell unit of a desired size by using the laser and then, the solar cell substrate 100 is cut. At the scribing step (S300), the scribing is performed by irradiating the laser in a direction in which the electrode pattern 130 is not directly processed. In the exemplary embodiment of the present invention, since the laser scribing is performed on the front surface of the solar cell substrate 100, the problem such as the increase in resistance, or the like, due to the electrode alloying caused when the electrode pattern 130 is directly cut by the laser does not occur. Therefore, the conversion efficiency of the solar cell is degraded even after the cell is cut. The scribing performed on the front surface of the solar cell substrate 100 may be performed in a direction traversing the direction of the electrode pattern 130 or a direction parallel with the direction of the electrode pattern 130. In the exemplary embodiment of the present invention, the laser scribing may sharp the tip shape of the cutting groove and when applying stress, the scribed grooves (see reference numeral ‘S’ of FIG. 5) serve to concentrate the stress, such that the laser scribing is very advantageous over the diamond blade scribing. In addition, in the case of the laser scribing, the diameter of the scribed groove is small, the depth control is facilitated, and the high-speed processing can be made.

Preferably, referring to FIG. 3, in the exemplary embodiment of the present invention, at the step (b) (S300), the scribing is performed in a direction at least including a vertical direction to the electrode pattern 130. The laser does not perform a direct role in processing the electrode pattern 130 by performing the scribing in a direction vertical to the electrode pattern 130 on the front surface of the solar cell substrate 100 and does not degrade the conversion efficiency of the solar cell even though each cell is cut after the scribing.

FIG. 3 shows that the scribing is performed in a direction vertical to the electrode pattern 130. However, the scribing may be performed on the front surface of the solar cell substrate 10 in a direction parallel with the electrode pattern 130, preferably, in parallel with the electrode pattern 130 via a space in which the electrode patterns 130 are formed.

Preferably, according to the exemplary embodiment of the present invention, the laser used for scribing has a wavelength according to one of infrared, visible, and ultraviolet bands. For example, all of the laser wavelengths of 1064 nm, 532 nm, 355 nm, 266 nm, and 213 nm may be used. Preferably, the shorter the wavelength, the cleaner processing may be implemented. Preferably, the laser may use nanosecond pulse laser, picosecond pulse laser, or femtosecond pulse laser according to the pulse duration at the time of the scribing processing. More preferably, when the laser beam pulse duration is 10 ps or more, due to the influence of the thermal conductivity through the inter-atom connection, as the pulse is short, the thermal damage may be reduced.

Referring to FIG. 1, at the step (c) (S500) that is the cell cutting step, each cell is cut along the scribing so as to form the solar cell. In this case, at the previous step (S300), since the scribed grooves (see reference numeral ‘S’ of FIG. 5) serve to concentrate stress, the cutting may be easily made along the scribed grooves by applying stress thereto. Preferably, the cutting is made along the scribed grooves by applying tension stress or shear stress thereto.

Next, another exemplary embodiment of the present invention will be described with reference to FIG. 2.

Referring to FIG. 2, the exemplary embodiment of the present invention further includes a defect detecting step (S400) that detects defect portions by the photoluminescence (PL) method prior to the step (c) (S500) after the step (b) (S300). After the scribing, for example, the defective cells present on the wafer substrate are selected by the photoluminescence (PL). FIG. 4 shows PL images after the scribing, wherein numbers 12 and 16 and number 32 are each divided as the defective products due to a surface scratch and defect badness, respectively. The photoluminescence (PL) is a method that observes light (light emission) emitted when larger energy than a band gap is applied to the solar cell substrate 100 in a light type. The PL, which is a method of observing light emitted after irradiating laser to the sample (solar cell substrate) without needing to connect the electrodes, unlike electroluminescence (EL), may observe characteristics without damaging the solar cell substrate 100. In the exemplary embodiment, the defective detection due to the photoluminescence is performed after the scribing step (S300) to detect defects that may occur in the scribing step (S300), such that good products having the excellent conversion efficiency of the solar cell can be selected.

Although not shown, the exemplary embodiment further includes a step of marking cells determined as badness after the above-mentioned defective detection step (S400). At the present step, the defective cells are displayed as a marker 55 and then, the marked cells are separated from the cells cut at the cutting step (S500).

Although not shown, the cut cells after the step (c) (S500) that is the step of cutting each cell are divided as the good product and the defective product. Preferably, after the cutting, the good product and the defective product selected by the PL are put in a tray.

The following [Table 1] is the comparison data of I-V test results in the wafer state for the solar cell wafer with results measured after cutting the cells at a size of 22×12 mm in a manner according to the exemplary embodiment of the present invention. As shown in [Table 1], even after cutting the cell unit according to the exemplary embodiment of the present invention, the photoelectric conversion efficiency of the solar cell is reduced from 19.36% to 19.14%, that is, by about 0.2%, such that the reduction width in the conversion efficiency is very small, thereby preventing the degradation in conversion efficiency of the solar cell. When performing the diamond blade cutting of the related art, the degradation in the conversion efficiency of about 3%, in the worse case, about 5% occurs. On the other hand, the exemplary embodiment of the present invention, it can be appreciated that the degradation in the photoelectric conversion efficiency is very small.

TABLE 1

| | | Before Cutting | After Cutting at Cell of |
|---|---|---|---|
| Item | Unit | Wafer | 22 × 12 mm |
| Voc | V | 0.64 | 0.64 |
| Isc | mA | 6155.94 | 108.73 |
| Jsc | mA/cm² | 41.35 | 41.19 |
| Fill Factor | % | 72.75 | 72.57 |
| Imax | mA | 5478.75 | 99.25 |
| Vmax | V | 0.53 | 0.51 |
| Pmax | mW | 2884 | 51 |
| Conversion | % | 19.36 | 19.14 |
| Efficiency | | | |
| R shunt | ohm | 2 | 941 |
| R series | ohm | 0.01 | 0.56 |

Next, an apparatus for producing a solar cell according to another exemplary embodiment of the present invention will be described with reference to the accompanying drawings. In connection with the operational method of the apparatus for producing a solar cell according to the exemplary embodiment of the present invention, the detailed exemplary embodiments of the method for producing a solar cell as described above will be referred and therefore, it is to be noted that the repeated contents as the contents described in the above-mentioned exemplary embodiments may be omitted.

FIG. 5 is a diagram schematically showing the exemplary embodiment of the apparatus for producing a solar cell according to the exemplary embodiment of the present invention and it is to be noted that the apparatus from which some components shown in FIG. 5 are excluded may be used. For example, the apparatus for producing a solar cell may be implemented in a type from which components such as a photoluminescence unit, a marker, or the like, are excluded from components shown in FIG. 5.

Being described with reference to FIG. 5, the apparatus for producing a solar cell according to the exemplary embodiment of the present invention is configured to include a control unit 10, a stage unit 20, a scribing unit 30, and a cell cutting unit 40.

In FIG. 5, the control unit 10 controls the operations of each component. Preferably, the control unit 10 controls the operation of each component according to the preset programs.

The stage unit 20 of FIG. 5 transfers the rear contact solar cell substrate 100 having the electrode pattern 130 formed on the rear surface thereof according to the control of the control unit 10. Although not shown, the stage unit 20 includes, for example, a conveyor or a rotating unit to transfer the solar cell substrate 100 to a place in which each component is disposed. Preferably, the solar cell substrate 100 may be transferred by attaching the bottom of the cell substrate 100 to a dicing tape 43, for example, a UV dicing tape.

Preferably, according to the exemplary embodiment of the present invention, the rear surface of the cell substrate 100 transferred by the stage unit 20 is alternately provided with the positive (+) and negative (−) electrode patterns 130 penetrating through the oxide layer or the passivation pattern 120.

The scribing unit 30 performs the scribing by irradiating laser to the front surface of the solar cell substrate 100 transferred through the stage unit 20 on which the electrode pattern 130 is not formed. The scribing unit 30 performs the scribing by irradiating the laser in a direction in which the electrode pattern 130 is not directly processed according to the control of the control unit 10. In the exemplary embodiment, the scribing may be performed in a direction traversing the electrode pattern 130 or a direction parallel with the electrode pattern 130 on the front surface of the solar cell on which the electrode pattern 130 is not formed.

Preferably, according to the exemplary embodiment of the present invention, as shown in FIG. 3, the scribing unit 30 performs the scribing in a direction including at least a direction vertical to the electrode pattern 130.

Preferably, in another exemplary embodiment of the present invention, the laser irradiated from the scribing unit 30 has a wavelength according to one of infrared, visible, and ultraviolet bands. For example, all of the laser wavelengths of 1064 nm, 532 nm, 355 nm, 266 nm, and 213 nm may be used. Preferably, the shorter the wavelength, the cleaner processing may be implemented. Preferably, the laser may use nanosecond pulse laser, picosecond pulse laser, or femtosecond pulse laser according to the pulse duration at the time of the scribing processing. More preferably, the shorter the pulse duration, the more thermal damage may be reduced.

Preferably, according to another exemplary embodiment of the present invention, as shown in FIG. 5, the scribing unit 30 is configured to include an air nozzle 35 for removing the foreign materials on the surface of the solar cell substrate 100. The foreign materials are smeared on the surface of the cell substrate 100 at the time of the laser scribing and the defects may occur when the scribing is made on the foreign materials.

In addition, referring to FIG. 5, according to another exemplary embodiment of the present invention, the scribing unit 30 is configured to include a reflection mirror 32 that reflects the laser irradiated from a laser irradiator 31 and a focusing lens 33 that focuses the reflected laser.

In the exemplary embodiment of the present invention, the cell cutting unit 40 accepts the scribed solar cell substrate 100 through the stage unit 20 to cut the substrate 100 in each cell according to the scribing so as to form the solar cell. The cutting is made along the scribed grooves by concentrating stress on the scribed grooves. Preferably, the cell cutting unit 40 cuts the solar cell substrate 100 along the scribed grooves performed by the scribing unit 30 by applying the tension stress or the shear stress thereto.

The exemplary embodiment of the present invention will be described with reference to FIG. 5.

Referring to FIG. 5, the exemplary embodiment of the present invention further includes the photoluminescence unit 50 capturing the emission image by irradiating the laser to the scribed cell substrate 100. The apparatus for producing a solar cell according to the exemplary embodiment of the present invention reads and detects the defective portions from the image captured from the photoluminescence unit 50 according to the control of the control unit 10. The defective portions are detected through the image reading by comparing pixel values extracted from the captured image with the reference and displaying the comparison results. The photoluminescence unit 50 is configured to include the laser irradiator 51 and the camera unit 53 capturing the image. Preferably, referring to FIG. 5, the camera unit 53 capturing the light image emitted from the solar cell substrate 100 according to the laser irradiation is configured to include a camera 53a, a lens 53b, and a filter 53c.

Preferably, as shown in FIG. 5, in the apparatus for producing a solar cell according to the exemplary embodiment of the present invention, the photoluminescence unit 50 is configured to include the marker 55 that marks the cell including the detected defective portion.

As set forth above, the exemplary embodiment of the present invention can cut the rear contact solar cell in the wafer substrate unit so as to minimize the degradation in conversion efficiency even after the solar cell in the wafer substrate unit, in particular, the rear contact solar cell in the wafer substrate unit is cut into the cell unit during manufacturing the small solar cell.

The exemplary embodiment of the present invention can minimize the degradation in conversion efficiency of the solar cell even after the rear contact solar cell is cut into the cell unit, by performing the laser scribing on the front surface of the solar cell substrate on which the electrode patterns of the rear contact solar cell are not formed and performing the cutting along the scribed grooves.

In particular, the exemplary embodiment of the present invention can prevent the degradation in conversion efficiency of the solar cell due to the electrode alloying caused at the time of the laser processing, by cutting the rear contact solar cell into the cell unit by performing the laser scribing on the top surface of the rear contact solar cell on which the electrode patterns are not formed.

It is obvious that various effects directly stated according to various exemplary embodiment of the present invention may be derived by those skilled in the art from various configurations according to the exemplary embodiments of the present invention.

The accompanying drawings and the above-mentioned exemplary embodiments have been illustratively provided in order to assist in understanding of those skilled in the art to which the present invention pertains. While this invention has been described in connection with what is presently considered to be practical exemplary embodiments, it is to be understood that the invention is not limited to the disclosed embodiments. Therefore, it will be apparent to those skilled in the art that various modifications, substitutions and equivalents can be made in the present invention without departing from the spirit or scope of the inventions.

What is claimed is:

1. A method for producing a solar cell, comprising
(a) preparing a rear contact solar cell substrate having electrode patterns formed on a rear surface thereof;
(b) performing scribing on a front surface of the substrate on which the electrode patterns are not formed, by using laser; and
(c) cutting the substrate in each cell along the scribing so as to form the solar cell.

2. The method according to claim 1, wherein at the step (b), the scribing is performed in at least one direction including a direction vertical to the electrode patterns.

3. The method according to claim 1, wherein at the step (a), the prepared substrate has positive (+) and negative (−) electrode patterns penetrating through a passivation pattern and alternately formed on the rear surface thereof.

4. The method according to claim 1, further comprising detecting defects that detect defective portions by a photoluminescence method prior to the step (c) after the step (b).

5. The method according to claim 4, further comprising marking on the cell determined as defects after the step of detecting defects.

6. The method according to claim 4, wherein after the step (c), the cut cells are divided as good products and defective products.

7. The method according to claim 1, wherein the laser used for the scribing has a wavelength according to one of infrared, visible, and ultraviolet bands.

8. The method according to claim 2, wherein the laser used for the scribing has a wavelength according to one of infrared, visible, and ultraviolet bands.

9. The method according to claim 4, wherein the laser used for the scribing has a wavelength according to one of infrared, visible, and ultraviolet bands.

10. An apparatus for producing a solar cell, comprising:
a control unit that controls an operation of each component;
a stage unit that transfers a rear contact solar cell substrate having electrode patterns formed on a rear surface thereof according to a control of the control unit;
a scribing unit that performs scribing by irradiating laser to a front surface of the substrate transferred through the stage unit on which the electrode patterns are not formed; and
a cell cutting unit that accepts the scribed substrate through the stage unit and cuts the substrate in each cell along the scribing so as to form the solar cell.

11. The apparatus according to claim 10, wherein the scribing unit performs the scribing in at least one direction including a direction vertical to the electrode patterns.

12. The apparatus according to claim 10, wherein the scribing unit includes an air nozzle that removes foreign materials on the surface of the substrate.

13. The apparatus according to claim 10, wherein the scribing unit includes a reflection mirror that reflects laser irradiated from a laser irradiator and a focusing lens that focuses the reflected laser.

14. The apparatus according to claim 10, further comprising a photoluminescence unit that captures an emission image by irradiating laser to the scribed substrate,
wherein defective portions are read and detected from the image captured from the photoluminescence unit.

15. The apparatus according to claim 14, wherein the photoluminescence unit includes a marker that marks a cell including the detected defective portions.

16. The apparatus according to claim 10, wherein the laser irradiated from the scribing unit has a wavelength according to one of infrared, visible, and ultraviolet bands.

17. The apparatus according to claim 11, wherein the laser irradiated from the scribing unit has a wavelength according to one of infrared, visible, and ultraviolet bands.

18. The apparatus according to claim 14, wherein the laser irradiated from the scribing unit has a wavelength according to one of infrared, visible, and ultraviolet bands.
